(19) United States
(12) Patent Application Publication
(10) Pub. No.: US 2009/0303816 A1
(43) Pub. Date: Dec. 10, 2009

(54) SEMICONDUCTOR MEMORY APPARATUS AND METHOD OF CONTROLLING REDUNDANCY THEREOF

(75) Inventor: Jin Hee CHO, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 12/541,683

(22) Filed: Aug. 14, 2009

Related U.S. Application Data
(62) Division of application No. 11/822,359, filed on Jul. 5, 2007.

(30) Foreign Application Priority Data
Oct. 13, 2006 (KR) 10-2006-0099709

(51) Int. Cl. G11C 29/00; G11C 17/18; G11C 7/00

(52) U.S. Cl. 365/200; 365/225.7; 365/222

(57) ABSTRACT

A semiconductor memory apparatus includes a memory cell array. A redundancy controller that determines whether to activate a redundancy enable signal on the basis of a refresh signal and outputs the redundancy enable signal. A comparator outputs a redundancy selection signal in response to the redundancy enable signal and an address signal. A decoder activates an area corresponding to the redundancy selection signal in the memory cell array.

### CROSS-REFERENCE TO RELATED PATENT APPLICATION

This application is a divisional of U.S. patent application Ser. No. 11/822,359, filed Jul. 5, 2007, the subject matter of which application is incorporated herein by reference in its entirety.

This application claims the benefit of Korean Patent Application No. 10-2006-0099709, filed on Oct. 13, 2006, in the Korean Intellectual Property Office, the disclosure of which is incorporated herein in its entirety by reference.

### BACKGROUND OF THE INVENTION

1. Technical Field

The present invention relates to a semiconductor memory apparatus, and more particularly, to a semiconductor memory apparatus having redundancy memory cells and a method of controlling redundancy thereof.

2. Related Art

In general, semiconductor memory apparatuses each have redundancy memory cells capable of replacing defective memory cells during a manufacturing process and a redundancy circuit for controlling the redundancy memory cells.

The redundancy circuit is operated to determine whether to select redundancy memory cells instead of the defective memory cells during an active period for executing a read or write command input from the outside of the semiconductor memory apparatus. In addition, the redundancy circuit also determines whether to replace the defective memory cells with the redundancy memory cells during a refresh period.

However, the refresh operation is performed in a predetermined direction, that is, a row direction, not a column direction, which makes it unnecessary to operate the redundancy circuit during the refresh period.

As described above, in the semiconductor memory apparatus according to the related art, the redundancy circuit is also operated during the refresh period, which results in an increase in current consumption. In particular, since the performance of the semiconductor memory apparatus greatly depends on the current consumption, it is important to reduce the current consumption of the semiconductor memory apparatus.

### SUMMARY OF THE INVENTION

The embodiments of the present invention provide a semiconductor memory apparatus capable of reducing current consumption and a method of controlling redundancy of the semiconductor memory apparatus.

An embodiment of the present invention provides a semiconductor memory apparatus including: a memory cell array; a redundancy controller that determines whether to activate a redundancy enable signal on the basis of a refresh signal and outputs the redundancy enable signal; a comparator that outputs a redundancy selection signal in response to the redundancy enable signal and an address signal; and a decoder that activates an area corresponding to the redundancy selection signal in the memory cell array.

Another embodiment of the present invention provides a method of controlling redundancy of a semiconductor memory apparatus including a memory cell array and a redundancy controller that outputs a redundancy enable signal for determining whether to perform redundancy on a defective area of the memory cell array. The method includes: determining whether the semiconductor memory apparatus is in an operation mode for performing a read or write command input from the outside; and controlling the redundancy controller such that the redundancy enable signal is not output when the semiconductor memory apparatus is not in the operation mode for performing a read or write command input from the outside.

### BRIEF DESCRIPTION OF THE DRAWINGS

FIG. 1 is a block diagram illustrating the structure of a semiconductor memory apparatus according to an embodiment of the invention.

FIG. 2 is a circuit diagram illustrating an example of a redundancy controller according to an embodiment of the invention.

FIG. 3 is a timing chart illustrating a redundancy control operation of the redundancy controller shown in FIG. 2.

FIG. 4 is a circuit diagram illustrating another example of the redundancy controller according to an embodiment of the invention.

FIG. 5 is a circuit diagram illustrating still another example of the redundancy controller according to an embodiment of the invention.

FIG. 6 is a timing chart illustrating a redundancy control operation of the redundancy controllers shown in FIGS. 4 and 5.

### DESCRIPTION OF EXEMPLARY EMBODIMENT

A semiconductor memory apparatus and a method of controlling redundancy thereof according to embodiments of the present invention will now be described in detail with reference to the accompanying drawings.

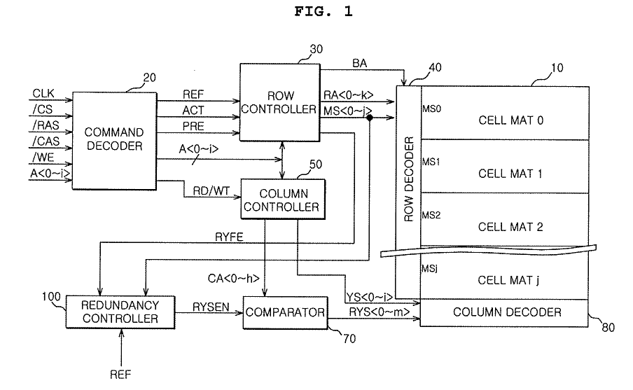

As shown in FIG. 1, a semiconductor memory apparatus according to an embodiment of the invention includes a memory cell array 10, a command decoder 20, a row controller 30, a row decoder 40, a column controller 50, a redundancy controller 100, a comparator 70, and a column decoder 80.

The memory cell array 10 is a group of memory cells arranged in a matrix. The memory cell array may be called a memory bank, and a semiconductor memory apparatus may include a plurality of memory banks according to its memory capacity. The memory cell array 10 has a plurality of small areas and a redundancy area that will be replaced with a defective area among the plurality of small areas. The small areas are arranged in a row direction and are called cell mats, which correspond to zeroth to j-th cell mats. The redundancy area may be a separate area that will replace a defective row or column, and corresponds to a column redundancy area in this embodiment of the invention.

The command decoder 20 decodes a clock signal CLK, a chip selection signal /CS, a row address strobe signal /RAS, a column address strobe signal /CAS, a write enable signal /WE, and an address A<0:i> and outputs a refresh signal REF, an active signal ACT, a precharge signal PRE, the address A<0:i>, and a read/write signal RD/WT. The chip selection signal /CS is used to operate a chip including the semiconductor memory apparatus.

The row controller 30 receives the refresh signal REF, the active signal ACT, and the precharge signal PRE and outputs a bank active signal BA, a row address RA<0:k>, a mat selection signal MS<0:j>, and a redundancy signal RYFE. The active signal BA is used to operate the memory bank. The mat selection signal MS<0:j> is used to select one of the cell mats (the zeroth to j-th cell mats), which are small areas of the memory cell array 10.

The row decoder 40 activates wordlines that are connected to a row of cells corresponding to the row address RA<0:k> and the mat selection signal MS<0:j> in the memory cell array 10.

The column controller 50 receives the address A<0:i> and the read/write signal RD/WT and outputs a column address CA<0:h> and a column selection signal YS<0:i>.

The redundancy controller 100 receives the redundancy reset signal RYFE and the mat selection signal MS<0:j>, and uses an operation mode signal, that is, the refresh signal REF, a redundancy reset signal RYFE, and the mat selection signal MS<0:j> to output a column redundancy enable signal RYSEN.

The comparator 70 outputs a column redundancy selection signal RYS<0:m> on the basis of the column address CA<0:h> and the column redundancy enable signal RYSEN.

The column decoder 80 activates bit lines that are connected to a column of cells corresponding to the column redundancy selection signal RYS<0:m> or the column selection signal YS<0:i>.

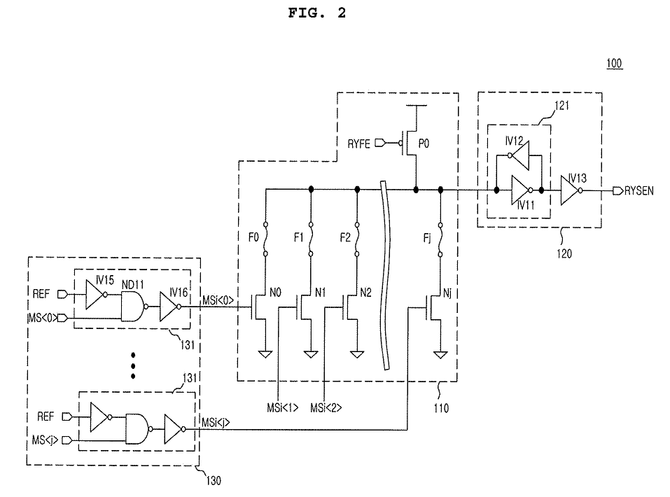

The redundancy controller 100 may have various configurations, but three embodiments of the redundancy controller 100 will be described. As shown in FIG. 2, the redundancy controller 100 according to a first embodiment of the invention includes a redundancy setting unit 110, a signal output unit 120, and a controller 130.

The redundancy setting unit 110 stores information on defects occurring in a plurality of cell mats (the zeroth to j-th cell mats) in the memory cell array 10, and outputs the information on the defects in response to a mat selection signal MSi<0:j> transmitted from the controller 130. The redundancy setting unit 110 includes a plurality of fuses F0 to Fj each having one end connected to a common point, a plurality of first transistors N0 to Nj that are connected between respective ones of second ends of the plurality of fuses F0 to Fi and are turned on in response to the mat selection signals MSi<0:j>, and a second transistor P0 that is turned on in response to the redundancy reset signal RYFE and supplies power through the one end of each of the fuses F0 to Fj. It is possible to store the defect information of the plurality of cell mats (the zeroth to j-th cell mats) by cutting the fuses F0 to Fj.

The signal output unit 120 outputs a redundancy enable signal RYSEN on the basis of the defect information stored in the redundancy setting unit 110. The signal output unit 120 includes a latch 121 connected to an output terminal of the redundancy setting unit 110 and an inverter IV13 connected to an output terminal of the latch 121.

The controller 130 prevents the mat selection signal MS<0:j> from being input to the redundancy setting unit 110 in response to the refresh signal REF. The controller 130 includes a number of logic circuits 131 corresponding to the number of bits of the mat selection signal MS<0:j>. The logic circuit 131 cuts off the input of the mat selection signal MS<0:j> to the redundancy setting unit 110 when the refresh signal REF is enabled. The logic circuit 131 includes a first inverter IV15 that receives the refresh signal REF, a NAND gate ND11 that receives an output signal from the first inverter IV15 and the mat selection signal MS<0:j>, and a second inverter IV16 that receives an output signal of the NAND gate ND11 and outputs the mat selection signal MSi<0:j>.

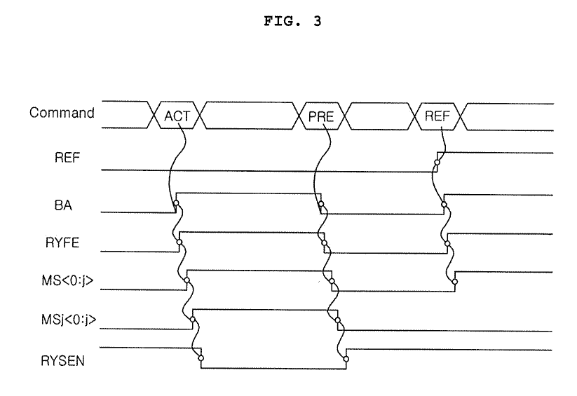

A redundancy control operation of the semiconductor memory apparatus including the redundancy controller shown in FIG. 2 according to an embodiment of the invention will be described below with reference of FIG. 3.

When a precharge command PRE is input, the bank active signal BA is disabled, and the redundancy reset signal RYFE and the mat selection signal MS<0:j> are also disabled at a predetermined time interval. In addition, when the precharge command PRE is input, the semiconductor memory apparatus is in a standby state without performing reading and writing operations.

The redundancy reset signal RYFE and the mat selection signal MS<0:j> are disabled, and the refresh signal REF is also disabled since the semiconductor memory apparatus is in the precharge state.

Since the refresh signal REF is in a disabled state, the controller 130 shown in FIG. 2 can output the mat selection signal MS<0:j>. However, since the mat selection signal MS<0:j> is in a disabled state, the mat selection signal MSi<0:j> output from the controller 130 is disabled.

Since the redundancy reset signal RYFE is in a disabled state, the second transistor P0 of the redundancy setting unit 110 is turned on. Since the mat selection signal MSi<0:j> is in the disabled state, the redundancy setting unit 110 outputs a high-level signal regardless of the cut state of the fuses F0 to Fj.

The signal output unit 120 resets the redundancy enable signal RYSEN to a high level since the redundancy setting unit 110 outputs a high-level signal during the precharge operation.

Among the fuses F0 to Fj, a fuse corresponding to a defective column cell is cut.

When the active signal ACT is enabled in an active mode, the bank active signal BA is enabled, and the redundancy reset signal RYFE and the mat selection signal MS<0: j> are sequentially enabled after a predetermined time.

When the redundancy reset signal RYFE is enabled, the second transistor P0 of the redundancy setting unit 110 shown in FIG. 2 is turned off. Meanwhile, one of the mat selection signals MS<0:j> corresponding to the row address RA<0:k> is enabled.

Since the refresh signal REF is in the disabled state, the controller 130 shown in FIG. 2 outputs a mat selection signal MSi<0:j> having the same logic level as that of the original mat selection signal MS<0:j>.

The redundancy enable signal RYSEN is output at a low level or a high level according to the state of one of the mat selection signals MSi<0:j> corresponding to the row address RA<0:k> and the cut state of one of the fuses F0 to Fj corresponding to the one mat selection signal.

For example, when the mat selection signal MS<0> is enabled and the fuse F0 corresponding thereto is cut, the mat selection signal MSi<0> output from the controller 130 is enabled, and the redundancy enable signal RYSEN is maintained at a high level.

However, when the mat selection signal MS<0> is enabled, but the fuse F0 corresponding thereto is not cut, the mat selection signal MSi<0> output from the controller 130 is enabled, and the transistor N0 is turned on. Since the transistor N0 is in the on state and the fuse F0 is not cut, a low-level redundancy enable signal RYSEN is output.

When a high-level redundancy enable signal RYSEN is output, the comparator 70 outputs a column redundancy selection signal RYS<0:m> corresponding to a column redundancy cell that can be replaced with the column address CA<0:h>.

The column decoder 80 activates bit lines connected to a column of cells corresponding to the column redundancy selection signal RYS<0:m>.

When the refresh signal REF is enabled in a refresh mode, the bank active signal BA is enabled, similar to the active mode, and the redundancy reset signal RYFE and the mat selection signal MS<0:j> are sequentially enabled after a predetermined time.

The refresh mode may be classified into a self refresh mode that is performed according to an external command and an auto refresh mode that is performed according to its own set data regardless of an external command. The refresh signal REF according to this embodiment of the invention can be used for both the self refresh mode and the auto refresh mode. This is because this embodiment of the invention can be applied to both the self refresh mode and the auto refresh mode.

When the redundancy reset signal RYFE is enabled, the second transistor P0 of the redundancy setting unit 110 shown in FIG. 2 is turned off. Meanwhile, one of the mat selection signals MS<0:j> corresponding to the row address RA<0:k> is enabled.

Since the refresh signal REF is in an enable state, the mat selection signals MSi<0:j> output from the controller 130 shown in FIG. 2 is disabled regardless of the state of the original mat selection signal MS<0:j>.

Therefore, the redundancy enable signal RYSEN is reset to a high level during a refresh period regardless of the cut state of the fuses F0 to Fj of the redundancy setting unit 110 shown in FIG. 2.

For example, when the mat selection signal MS<0> is enabled and the fuse F0 corresponding thereto is cut, the refresh signal REF is enabled and the mat selection signal MSi<0> output from the controller 130 is disabled, so that the redundancy enable signal RYSEN is reset to a high level regardless of the cut state of the fuse F0.

Since the refresh mode is performed on only rows of cells regardless of columns, the column addresses CA<0:h> and the column selection signals YS<0:i> are not supplied. Therefore, the comparator 70 and the column decoder 80 do not operate.

The semiconductor memory apparatus including the redundancy controller 100 shown in FIG. 2 according to this embodiment of the invention cuts off the input of the mat selection signal MS<0> such that an internal circuit of the redundancy controller 100 does not operate, thereby preventing unnecessary current consumption.

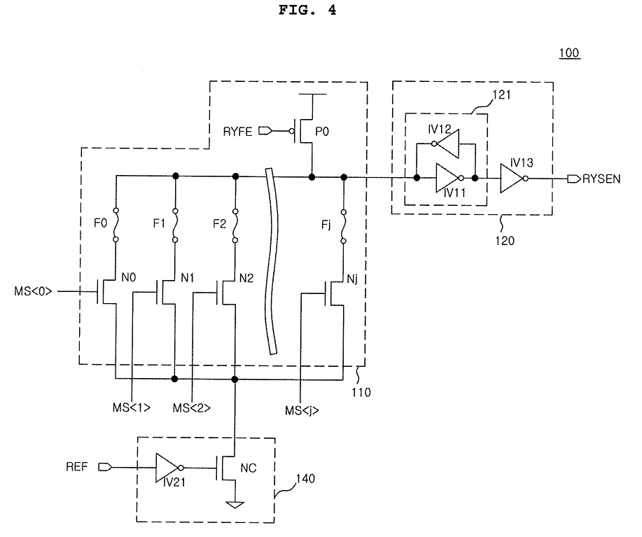

As shown in FIG. 4, a second embodiment of the redundancy controller 100 includes a redundancy setting unit 110, a signal output unit 120, and a controller 140. The operations of the redundancy setting unit 110 and the signal output unit 120 are the same as those in the first embodiment shown in FIG. 2, and thus a description thereof will be omitted. The controller 140 cuts off the flow of current through the redundancy setting unit 110 to stop the operation of the redundancy setting unit 110 in response to the refresh signal REF, and cuts off the output of defect information regardless of the input of the mat selection signal MS<0:j>. The controller 140 includes an inverter IV21 that receives the refresh signal REF and a transistor NC that is connected between the redundancy setting unit 110 and a ground terminal and is turned off in response to an output signal from the inverter IV21.

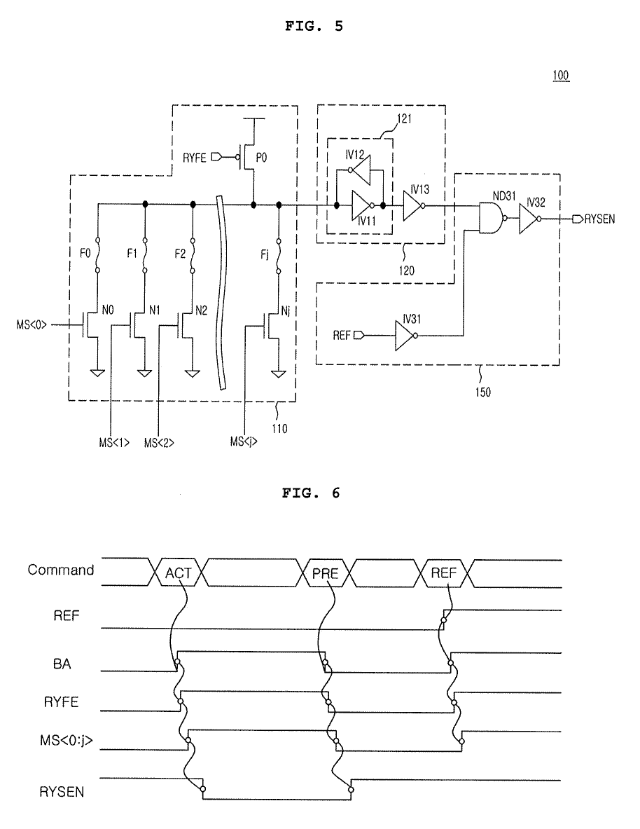

As shown in FIG. 5, a third embodiment of the redundancy controller 100 includes a redundancy setting unit 110, a signal output unit 120, and a controller 150. The operations of the redundancy setting unit 110 and the signal output unit 120 are the same as those in the first embodiment shown in FIG. 2, and thus a description thereof will be omitted. When the refresh signal REF is enabled, the controller 150 cuts off the output of a redundancy enable signal RYSEN from the signal output unit 120. The controller 150 includes a first inverter IV31 that receives the refresh signal REF, a NAND gate ND31 that receives an output signal of the signal output unit 120 and an output signal of the first inverter IV31, and a second inverter IV32 that receives an output signal of the NAND gate ND31.

The second and third embodiments differ from the first embodiment in that the second embodiment including the redundancy controller 100 shown in FIG. 4 cuts off the flow of current through the redundancy setting unit 110 regardless of the input of the mat selection signal MS<0> and the third embodiment including the redundancy controller 100 shown in FIG. 2 cuts off the output of the signal output unit 120.

A method of controlling the redundancy of the semiconductor memory apparatuses including the redundancy controllers 100 shown in FIGS. 4 and 5 according to the second and third embodiments of the invention will be described with reference to a timing chart shown in FIG. 6. That is, comparing the timing chart shown in FIG. 6 with the timing chart shown in FIG. 3, the second and third embodiments are similar to the first embodiment in that the redundancy enable signal RYSEN is not output in the refresh mode, that is, the redundancy enable signal RYSEN is reset to prevent toggling. Therefore, a description of a redundancy operation shown in FIG. 6 will be omitted.

These embodiments of the invention cut off the input of the mat selection signal MS<0>, the flow of current through the redundancy controller 110, or the output of the signal output unit 120 to prevent unnecessary current consumption.

It will be apparent to those skilled in the art that various modifications and changes may be made without departing from the scope and spirit of the present invention. Therefore, it should be understood that the above embodiments are not limitative, but illustrative in all aspects. The scope of the present invention is defined by the appended claims rather than by the description preceding them, and therefore all changes and modifications that fall within metes and bounds of the claims, or equivalents of such metes and bounds are therefore intended to be embraced by the claims.

The semiconductor memory apparatuses according to the embodiments of the invention prevent unnecessary current consumption due to the operation of the redundancy controller in the refresh mode, thereby considerably reducing the overall current consumption.

What is claimed is:

1. A semiconductor memory apparatus comprising:
a memory cell array;
a redundancy controller configured to determine whether to activate a redundancy enable signal on the basis of a refresh signal and outputs the redundancy enable signal;
a comparator configured to output a redundancy selection signal in response to the redundancy enable signal and an address signal; and
a decoder configured to activate an area corresponding to the redundancy selection signal in the memory cell array,
wherein the redundancy controller includes:
a redundancy setting unit that stores information on defects occurring in the memory cell array and outputs the information on defects in response to input of a selection signal for selecting a predetermined area of the memory cell array and including an output terminal;
a signal output unit that outputs the redundancy enable signal on the basis of the information on defects stored in the redundancy setting unit; and
a control unit that prevents a source current from flowing to the redundancy setting unit in response to the refresh signal to cut off the output of the information on defects regardless of the input of the selection signal.

2. The semiconductor memory apparatus according to claim 1,
wherein the redundancy setting unit includes:
a plurality of fuses each having one terminal connected to a common point and a second terminal; and
a plurality of switching elements that are respectively connected between respective ones of the second terminals of the plurality of fuses and the ground terminal and are turned on in response to the selection signal.

3. The semiconductor memory apparatus according to claim 1,
wherein the signal output unit includes:
a latch that is connected to the output terminal of the redundancy setting unit to provide an output signal; and
an inverting element that receives the output signal of the latch.

4. The semiconductor memory apparatus according to claim 1,
wherein the control unit includes a logic circuit that is connected between the redundancy setting unit and a ground terminal and cuts off the flow of current through the redundancy setting unit when the refresh signal is enabled.

5. A semiconductor memory apparatus comprising:
a memory cell array;
a redundancy controller configured to cut off input of a source current for generating a redundancy enable signal in response to a refresh signal to inactivate the redundancy enable signal and outputs the redundancy enable signal;
a comparator configured to output a redundancy selection signal in response to the redundancy enable signal and an address signal; and
a decoder configured to activate an area corresponding to the redundancy selection signal in the memory cell array.

6. The semiconductor memory apparatus according to claim
wherein the redundancy controller includes:
a redundancy setting unit including an output terminal and that stores information on defects occurring in the memory cell array and can output the information on defects in response to input of a selection signal for selecting a predetermined area of the memory cell array;
a signal output unit that outputs the redundancy enable signal on the basis of the information on defects stored in the redundancy setting unit; and
a control unit that prevents the source current from flowing to the redundancy setting unit in response to the refresh signal to cut off the output of the defect information regardless of the input of the selection signal.

7. The semiconductor memory apparatus according to claim 6,
wherein the redundancy setting unit includes:
a plurality of fuses each having one terminal connected to a common point and a second terminal; and
a plurality of switching elements that are respectively connected between respective ones of the second terminals of the plurality of fuses and a ground terminal and are turned on in response to the selection signal.

8. The semiconductor memory apparatus according to claim 7,
wherein the redundancy setting unit further includes:
a switching element that is turned on in response to a reset signal to supply power through one of the terminals of each of the plurality of fuses.

9. The semiconductor memory apparatus according to claim 6,
wherein the signal output unit includes:
a latch that is connected to the output terminal of the redundancy setting unit and provides an output signal; and
an inverting element that receives the output signal of the latch.

10. The semiconductor memory apparatus according to claim 6,
wherein the control unit includes a logic circuit that is connected between the redundancy setting unit and a ground terminal and cuts off the flow of current through the redundancy setting unit when the refresh signal is enabled.

11. The semiconductor memory apparatus according to claim 10,
wherein the logic circuit includes:
an inverting element that receives the refresh signal to provide an output signal; and
a switching element that is connected between the redundancy setting unit and the ground terminal and is turned off in response to the output signal of the inverting element.

12. The semiconductor memory apparatus according to claim 5,
wherein the area corresponding to the redundancy selection signal in the memory cell array is a column redundancy area for substituting a column of cells having defects in the memory cell array.

13. The semiconductor memory apparatus according to claim 5,
wherein the decoder is a column decoder for activating a column area corresponding to the redundancy selection signal.

14. A method of controlling redundancy of a semiconductor memory apparatus including a memory cell array and a redundancy controller that outputs a redundancy enable signal for determining whether to perform redundancy on a defective area of the memory cell array, comprising:
determining whether the semiconductor memory apparatus is in an operation mode for performing a read or write command input from the outside of the semiconductor memory apparatus; and
controlling the redundancy controller such that the redundancy enable signal is not output when the semiconductor memory apparatus is not in the operation mode for performing a read or write command input from the outside of the semiconductor memory apparatus,
wherein the controlling of the redundancy controller comprising cutting off the flow of current through the redundancy controller to cut off the output of the redundancy enable signal when the semiconductor memory apparatus is in a refresh mode.
